(19) United States
(12) Patent Application Publication
(10) Pub. No.: US 2025/0321269 A1
(43) Pub. Date: Oct. 16, 2025

(54) POSITIONING DEVICE AND POSITIONING METHOD FOR CHIP

(71) Applicant: SILICONWARE PRECISION INDUSTRIES CO., LTD., Taichung City (TW)

(72) Inventors: Ming-Jen LIN, Taichung City (TW); Hsun-Yung CHO, Taichung City (TW); Chun-Sung HUANG, Taichung City (TW); Ling-Fei CHENG, Taichung City (TW); Hsi-Chih CHEN, Taichung City (TW)

(21) Appl. No.: 18/895,062

(22) Filed: Sep. 24, 2024

(30) Foreign Application Priority Data
Apr. 16, 2024 (TW) 113114160

(51) Int. Cl. G01R 31/28; G01M 7/02; H01L 21/67; H01L 21/68

(52) U.S. Cl. CPC G01R 31/2893; G01M 7/022; H01L 21/67259; H01L 21/681

(57) ABSTRACT

A positioning device for chip, which includes: a carrying unit having a recess for accommodating and fixing a chip; a detection unit used to detect whether the chip is correctly placed in the recess; and a vibration positioning unit signally connected to the detection unit and mechanically connected to the carrying unit. When the detection unit detects that the chip is not correctly placed in the recess, the detection unit sends a trigger signal to drive the vibration positioning unit to vibrate the carrying unit to correctly place the chip in the recess, and vibration parameters of the vibration positioning unit correspond to physical specifications of the chip. By the implementation of the present disclosure, the chip can be correctly positioned and accommodated in the carrying unit, so as to avoid process delays or even defects caused by chip position deviation or mispositioning, thereby improving the process speed and yield.

### CROSS-REFERENCE TO RELATED APPLICATIONS

The present application is based upon and claims the right of priority to TW Patent Application No. 113114160, filed Apr. 16, 2024, the disclosure of which is hereby incorporated by reference herein in its entirety for all purposes.

### BACKGROUND

### 1. Technical Field

The present disclosure relates to a positioning device for chip, and more particularly, to a positioning device and a positioning method for chip.

### 2. Description of Related Art

In recent years, with the continuous development of semiconductor process technology, various high-performance electronic products have been continuously introduced. These electronic products have various integrated circuit (IC) chips with different functions inside. In the manufacturing process of these integrated circuit chips, integrated circuit packaging (IC packaging) plays a very important role. There are various forms of integrated circuit packaging, and each packaging form has its own particularities and applicable fields.

However, regardless of the form of packaging, the chip and the carrier board on which the chip is mounted must first undergo testing such as electrical testing to ensure that both the chip and the carrier board are normal, thereby ensuring the function and quality of the final product, wherein before the chip is to be processed or tested, it must be placed on a carrier, and each carrier has at least one groove for accommodating the chip, and wherein the carrier is then used to carry the chip to each work station for processing or measuring. However, due to the extremely small size and/or weight of integrated circuit chips, even if there are considerable differences in the chip scale, the differences will be extremely small to the machine or the operator. Therefore, it is difficult for conventional manufacturing processes and/or testing equipment to accurately position various chips with different physical specifications, such as size, weight, etc. As a result, the chip often deflects when being placed on the carrier, or even comes out from the carrier during positioning, causing interruption of the manufacturing process or measurement procedure. In serious cases, deviations in the position or attitude of the chip may lead to errors in processing or detection results, or even damage to the chip.

Therefore, how to overcome the various problems of the above-mentioned prior art has become an urgent problem that needs to be overcome in the current industry.

### SUMMARY

In view of the various deficiencies of the prior art, the present disclosure provides a positioning device for chip, which includes: a carrying unit having a recess for accommodating and fixing a chip; a detection unit used to detect whether the chip is correctly placed in the recess; and a vibration positioning unit signally connected to the detection unit and mechanically connected to the carrying unit; wherein when the detection unit detects that the chip is not correctly placed in the recess, the detection unit sends a trigger signal to drive the vibration positioning unit to vibrate the carrying unit, so that the chip is correctly placed in the recess, and vibration parameters of the vibration positioning unit correspond to physical specifications of the chip.

The present disclosure further provides a positioning method for chip, which includes: receiving and fixing a chip in a recess of a carrying unit; and detecting whether the chip is correctly placed in the recess by a detection unit, wherein if a detection result is incorrect, the detection unit sends a trigger signal to drive a vibration positioning unit to vibrate the carrying unit so that the chip is correctly placed in the recess; and wherein vibration parameters of the vibration positioning unit correspond to physical specifications of the chip.

In the aforementioned positioning device and positioning method for chip, the physical specifications of the chip include at least one of a size and a weight of the chip.

In the aforementioned positioning device and positioning method for chip, the vibration parameters of the vibration positioning unit include at least one of an amplitude and a frequency.

In the aforementioned positioning device and positioning method for chip, the positioning device for chip further includes an information device for setting the physical specifications of the chip and outputting the physical specifications of the chip to the vibration positioning unit, so that the vibration parameters of the vibration positioning unit correspond to the physical specifications of the chip.

In the aforementioned positioning device and positioning method for chip, the information device is a computer or a human-machine interface.

In the aforementioned positioning device and positioning method for chip, the positioning device for chip further includes a signal conversion unit signally connected to the information device and the vibration positioning unit, so that an output of the information device is converted into a driving signal to drive the vibration positioning unit to adjust its vibration.

In the aforementioned positioning device and positioning method for chip, the positioning device for chip further includes a vibration monitoring unit for monitoring an action of the vibration positioning unit.

In the aforementioned positioning device and positioning method for chip, the vibration monitoring unit is signally connected to the vibration positioning unit, so that the vibration positioning unit automatically adjusts or stops its vibration based on a data measured by the vibration monitoring unit.

As can be seen from the above, in the positioning device and positioning method for chip of the present disclosure, the corresponding (vibration) positioning parameters are preset in the positioning device for chip according to the physical specifications of the chip to ensure that the chip can be correctly positioned in its recess after being accommodated in the carrying unit. Therefore, the chip will not come out from the recess of the carrying unit or even be damaged, or it will be difficult to be adjusted to the correct receiving position because the parameters of the positioning operation are not set properly, thereby ensuring that the process will not be delayed, and thus improving the process yield and speed.

### BRIEF DESCRIPTION OF THE DRAWINGS

FIG. 1 is a flow chart of a positioning method for chip according to an embodiment of the present disclosure.

FIG. 2 is a schematic view of a positioning device for chip according to an embodiment of the present disclosure.

FIG. 3 is a schematic view showing that a chip is not correctly placed in a recess of a carrying unit.

FIG. 4 is a system block diagram of a positioning device for chip according to an embodiment of the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

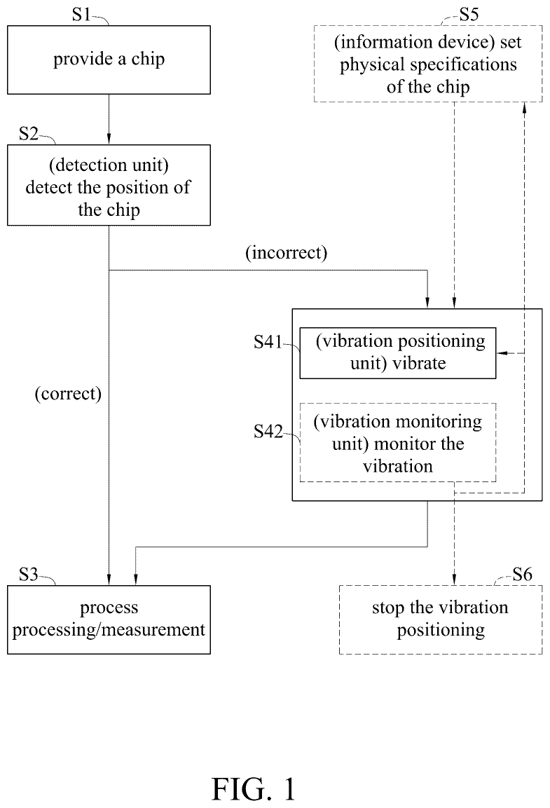

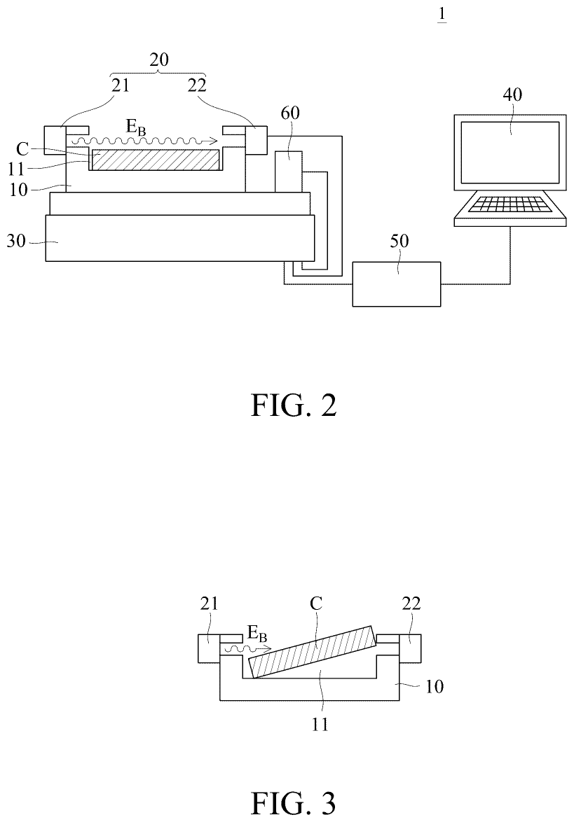

FIG. 1 is a flow chart of a positioning method for chip according to an embodiment of the present disclosure; FIG. 2 is a schematic view of a positioning device for chip according to an embodiment of the present disclosure; FIG. 3 is a schematic view of a chip that is not correctly placed in a recess of a carrying unit.

Please refer to FIG. 1 and FIG. 2 at the same time. First, step S1 is performed to provide a chip C. This is to place the chip C to be processed or measured in a recess 11 of the carrying unit 10 as shown in FIG. 2. The shape and size of the recess 11 are designed and manufactured based on the external shape and size of the chip C to be processed or measured, so that the chip C can be accommodated in and fixed in the recess 11.

Next, step S2 is performed, and a detection unit 20 is used to detect whether the position of the chip C is correctly placed in the recess 11. As shown in FIG. 2, the detection unit 20 may be, for example, an optical detection device including a beam emitter 21 and a beam receiver 22. When the detection result is correct, it means that the chip C is correctly accommodated in the recess 11, so that the beam EB emitted by the beam emitter 21 may pass above the chip C parallel to the upper surface of the chip C, and then be received by the beam receiver 22. At this point, step S3 can be performed to perform subsequent process processing or measurement on the chip C.

However, when the chip C is not correctly placed in the recess 11 as shown in FIG. 3, but presents an inclined posture in the recess 11, step S41 is performed at this time, so that the beam EB emitted by the beam emitter 21 of the detection unit 20 will be blocked by the chip C and cannot reach and be received by the beam receiver 22. When the detection unit 20 obtains such an incorrect detection result, it means that the chip C is not correctly accommodated in the recess 11 of the carrying unit 10, wherein the detection unit 20 will send a trigger signal to a vibration positioning unit 30 that is mechanically connected to the carrying unit 10, so that the vibration positioning unit 30 is triggered to vibrate, and drives the carrying unit 10 to vibrate via its mechanical connection with the carrying unit 10, such that the chip C can slide down into the bottom of the recess 11 via vibration and be correctly accommodated in the recess 11.

However, since various chips C have different physical specifications and characteristics such as size and weight, it is necessary to correctly and effectively facilitate the tilted chip C to reach the correct accommodation position via vibration. Therefore, the vibration parameters of the vibration positioning unit 30, such as vibration frequency and/or amplitude, must correspond to the physical specifications of the chip C.

In more detail, in the positioning method shown in this embodiment, the chip Cis first sucked or grabbed by a feeding equipment (not shown) and put into the recess 11 of the carrying unit 10. Then, as mentioned above, a detection unit 20, such as an infrared optical detector, emits an infrared beam EB horizontally with its beam emitter 21, and determines whether the chip C is correctly accommodated in the recess 11 based on whether the beam receiver 22 receives the infrared beam EB. When the beam receiver 22 does not receive the infrared beam EB emitted by the beam emitter 21, it means that the chip C is not correctly located in the recess 11, so the detection unit 20 will send a trigger signal to the vibration positioning unit 30.

The vibration positioning unit 30 is, for example, a vibration table driven by a motor (not shown). The vibration positioning unit 30 and the carrying unit 10 are mechanically connected. For example, the carrying unit 10 can be directly placed on the vibration positioning unit 30 as shown in FIG. 2, or the carrying unit 10 and the vibration positioning unit 30 can be connected via a connecting mechanism (not shown) such as a connecting rod/connecting arm. Any connection method that can transmit the vibration generated by the vibration positioning unit 30 to the carrying unit 10 can be applied, and the present embodiment is not particularly limited to as such.

When the trigger signal sent by the detection unit 20 is sent to the vibration positioning unit 30, the vibration positioning unit 30 will start to vibrate. The vibration parameters, such as amplitude, frequency, direction or mode, can be preset corresponding to at least one of the physical specifications such as the size, weight or natural frequency of the chip C. Therefore, when the vibration positioning unit 30 drives the carrying unit 10 to vibrate, it can adopt the best vibration method according to the physical specifications of the chip C to quickly and effectively vibrate it to the correct position in the recess 11 of the carrying unit 10, that is, the bottom of the recess 11. Moreover, because the vibration parameters provided by the vibration positioning unit 30 are specifically set according to the physical specifications of the chip C currently in the carrying unit 10, occurrence of problems such as the vibration amplitude being too large, causing the smaller or lighter chip C to be vibrated out of the recess 11, or the amplitude being too small, causing the larger or heavier chip C unable to effectively vibrate to the correct position can be avoided. Therefore, process delays and/or product damage caused by such errors can be avoided.

In a preferred embodiment, step S5 is further included. The positioning device for chip 1 further includes an information device 40, and the information device 40 is used to input/set the physical property specifications of the chip C, and output the physical property specifications and/or corresponding control instructions of the chip C to the vibration positioning unit 30, so that the vibration positioning unit 30 can accurately vibrate with parameters corresponding to the physical specifications of the chip C. Preferably, the information device 40 can preset and store the physical specifications of various chips C and their corresponding vibration parameters, so that the operator only needs to select the correct type or model of chip C in the information device 40 before starting the operation, and the information device 40 will transmit the correct information to the vibration positioning unit 30. In one embodiment, a computer is used as an example of the information device 40. In other embodiments, the information device 40 can also be a human-machine interface of an automatic control system. Any device that can input and set the physical specifications of the chip C and output the information and/or corresponding control instructions to the vibration positioning unit 30 can be used as the information device 40, and there is no particular limitation.

In another embodiment, the positioning device for chip 1 may also include a signal conversion unit 50, which is signally connected to the information device 40 and the vibration positioning unit 30 to convert the signal output by the information device 40 into a driving signal to drive the vibration positioning unit 30 to operate or adjust. The signal conversion unit 50 is, for example, a driver interface card installed in a computer or externally connected, and is used to convert instructions and/or signals issued by the computer as the information device 40 into driving signals that the vibration positioning unit 30 can recognize and act accordingly.

In yet another implementation aspect, step S42 is further included. The positioning device for chip 1 further includes a vibration monitoring unit 60, and the vibration monitoring unit 60 is used to monitor the action information of the vibration positioning unit 30, such as its vibration frequency and/or amplitude, etc., to ensure that all parameters of its vibration are maintained within the set range.

The vibration monitoring unit 60 may be, for example, an amplitude measuring instrument, or a monitoring unit composed of one or more accelerometers. There are many applicable elements and/or equipment. As long as it can accurately and effectively monitor various action parameters of the vibration positioning unit 30, it can be used as the vibration monitoring unit 60, and there is no particular limitation.

Preferably, step S6 is further included. The vibration monitoring unit 60 can further be signally connected to the vibration positioning unit 30, so that the vibration positioning unit 30 can automatically adjust or stop its vibration based on the data measured by the vibration monitoring unit 60. For example, when the vibration monitoring unit 60 detects that the amplitude of the vibration positioning unit 30 and/or the carrying unit 10 is not within a preset range, the monitoring data can first be transmitted to the vibration positioning unit 30, so that the vibration positioning unit 30 can adjust its action according to the difference between the monitoring data and the set value. However, if the vibration monitoring unit 60 continues to detect that the vibration parameters exceed the set range after transmitting the monitoring data to the vibration positioning unit 30, this means that there may be a fault or abnormality in the positioning device for chip 1. At this time, the vibration positioning unit 30 can be stopped for maintenance. Of course, the vibration monitoring unit 60 can also be further signally connected to the information device 40 to transmit the measured monitoring data to the information device 40 for display, processing and/or storage. The present embodiment is not particularly limited to as such.

Via the above-mentioned positioning method for chip, it can be ensured that the chip C can be correctly positioned in the recess 11 of the carrying unit 10 after being placed in the carrying unit 10. Accordingly, the chip C will not come out from the recess 11 of the carrying unit 10 or be difficult to be adjusted to the correct receiving position because the parameters of the positioning operation are not set properly, thereby ensuring that the process will not be delayed due to the above problems.

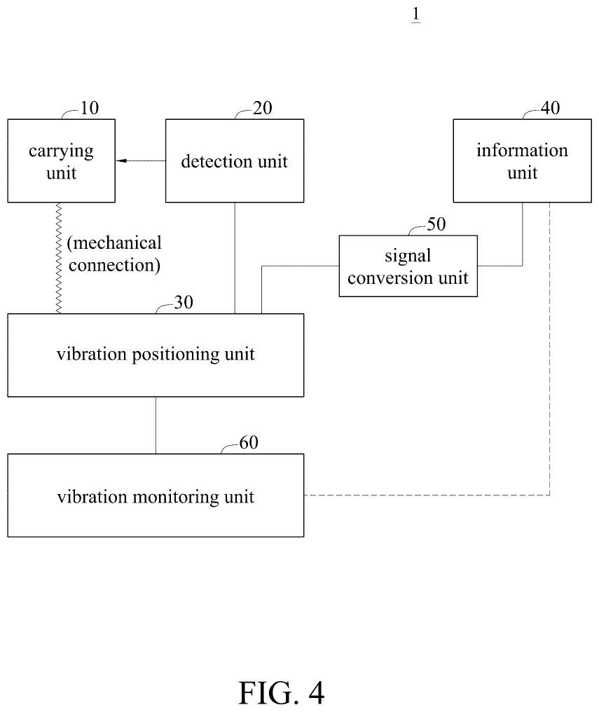

This embodiment also illustrates a positioning device for chip 1. As shown in FIGS. 2 and 4, the positioning device for chip 1 includes: a carrying unit 10 having a recess 11 for accommodating and fixing a chip C; a detection unit 20 used to detect whether the chip C is correctly placed in the recess 11; and a vibration positioning unit 30 signally connected to the detection unit 20 and mechanically connected to the carrying unit 10; wherein when the detection unit 20 detects that the chip C is not correctly placed in the recess 11, it sends a trigger signal to drive the vibration positioning unit 30 to vibrate the carrying unit 10, so that the chip Cis correctly placed in the recess 11, and the vibration parameters of the vibration positioning unit 30 correspond to the physical specifications of the chip C.

In one embodiment, the physical specifications of the chip C include at least one of the size and weight of the chip C.

In one embodiment, the vibration parameters of the vibration positioning unit 30 include at least one of amplitude or frequency.

In one embodiment, an information device 40 is included, which is used to set the physical specifications of the chip C, and output the physical specifications of the chip C to the vibration positioning unit 30 so that the vibration parameters of the vibration positioning unit 30 correspond to the physical specifications of the chip C.

In one embodiment, the information device 40 is a computer or a human-machine interface.

In one embodiment, it further includes a signal conversion unit 50, which is signally connected to the information device 40 and the vibration positioning unit 30, so that the output of the information device 40 is converted into a driving signal to drive the vibration positioning unit 30 to adjust its vibration.

In one embodiment, a vibration monitoring unit 60 is further included for monitoring the action of the vibration positioning unit 30.

In one embodiment, the vibration monitoring unit 60 is signally connected to the vibration positioning unit 30, so that the vibration positioning unit 30 automatically adjusts or stops its vibration based on the data measured by the vibration monitoring unit 60.

To sum up, in the positioning device and positioning method for chip of the present disclosure, the corresponding (vibration) positioning parameters are preset in the positioning device for chip according to the physical specifications of the chip to ensure that the chip can be correctly positioned in its recess after being accommodated in the carrying unit. Therefore, the chip will not come out from the recess of the carrying unit or even be damaged, or it will be difficult to be adjusted to the correct receiving position because the parameters of the positioning operation are not set properly, thereby ensuring that the process will not be delayed, and thus improving the process yield and speed.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A positioning device for chip, comprising:
a carrying unit having a recess for accommodating and fixing a chip;
a detection unit used to detect whether the chip is correctly placed in the recess; and
a vibration positioning unit signally connected to the detection unit and mechanically connected to the carrying unit;
wherein when the detection unit detects that the chip is not correctly placed in the recess, the detection unit sends a trigger signal to drive the vibration positioning unit to vibrate the carrying unit, so that the chip is correctly placed in the recess, and vibration parameters of the vibration positioning unit correspond to physical specifications of the chip.

2. The positioning device for chip of claim 1, wherein the physical specifications of the chip include at least one of a size and a weight of the chip.

3. The positioning device for chip of claim 1, wherein the vibration parameters of the vibration positioning unit include at least one of an amplitude and a frequency.

4. The positioning device chip of claim 1, further comprising an information device for setting the physical specifications of the chip and outputting the physical specifications of the chip to the vibration positioning unit, so that the vibration parameters of the vibration positioning unit correspond to the physical specifications of the chip.

5. The positioning device chip of claim 4, wherein the information device is a computer or a human-machine interface.

6. The positioning device for chip of claim 5, further comprising a signal conversion unit signally connected to the information device and the vibration positioning unit, so that an output of the information device is converted into a driving signal to drive the vibration positioning unit to adjust its vibration.

7. The positioning device for chip of claim 1, further comprising a vibration monitoring unit for monitoring an action of the vibration positioning unit.

8. The positioning device for chip of claim 7, wherein the vibration monitoring unit is signally connected to the vibration positioning unit, so that the vibration positioning unit automatically adjusts or stops its vibration based on a data measured by the vibration monitoring unit.

9. A positioning method for chip, comprising:
receiving and fixing a chip in a recess of a carrying unit; and
detecting whether the chip is correctly placed in the recess by a detection unit, wherein if a detection result is incorrect, the detection unit sends a trigger signal to drive a vibration positioning unit to vibrate the carrying unit to correctly place the chip in the recess; and wherein vibration parameters of the vibration positioning unit correspond to physical specifications of the chip.

10. The positioning method for chip of claim 9, wherein the physical specifications of the chip include at least one of a size and a weight of the chip.

11. The positioning method for chip of claim 9, wherein the vibration parameters of the vibration positioning unit include at least one of an amplitude and a frequency.

12. The positioning method for chip of claim 9, further comprising setting the physical specifications of the chip by an information device and outputting the physical specifications of the chip to the vibration positioning unit by the information device, so that the vibration parameters of the vibration positioning unit correspond to the physical specifications of the chip.

13. The positioning method for chip of claim 12, wherein the information device is a computer or a human-machine interface.

14. The positioning method for chip of claim 13, further comprising converting an output of the information device into a driving signal to drive the vibration positioning unit to adjust its vibration by a signal conversion unit signally connected to the information device and the vibration positioning unit.

15. The positioning method for chip of claim 9, further comprising monitoring an action of the vibration positioning unit by a vibration monitoring unit.

16. The positioning method for chip of claim 15, wherein the vibration monitoring unit is signally connected to the vibration positioning unit, so that the vibration positioning unit automatically adjusts or stops its vibration based on a data measured by the vibration monitoring unit.
